(19) United States
(12) Patent Application Publication
(10) Pub. No.: US 2021/0063457 A1
(43) Pub. Date: Mar. 4, 2021

(54) METHOD FOR MONITORING A SUPPLY SYSTEM OF A MOTOR VEHICLE

(71) Applicant: LEONI KABEL GMBH, ROTH (DE)

(72) Inventors: MICHAEL FROMMBERGER, NUERNBERG (DE); BASTIAN HITZ, POSTBAUER-HENG (DE); SEBASTIAN GOSS, ROTH (DE); MONIKA LENG, SPALT (DE)

(21) Appl. No.: 16/982,669

(22) PCT Filed: Mar. 19, 2019
(86) PCT No.: PCT/EP2019/056812

§ 371 Date: Sep. 21, 2020

(30) Foreign Application Priority Data
Mar. 19, 2018 (DE) 10 2018 204 182.2

(51) Int. Cl. G01R 31/00; G01R 31/08; G01H 17/00; B60L 53/60; B60L 53/18; H02J 7/00

(52) U.S. Cl. CPC G01R 31/006; G01R 31/08; H02J 7/0047; B60L 53/60; B60L 53/18; G01H 17/00

(57) ABSTRACT

A method monitors a supply system of a motor vehicle, in particular a high-voltage supply system of an electrically driven motor vehicle. The supply system contains at least two electric components which are connected together via a cable. The cable is part of the supply system which additionally has a number of sensors for monitoring at least one state variable of the supply system. State variable values which are ascertained by the sensors are used to infer the functionality of the supply system.

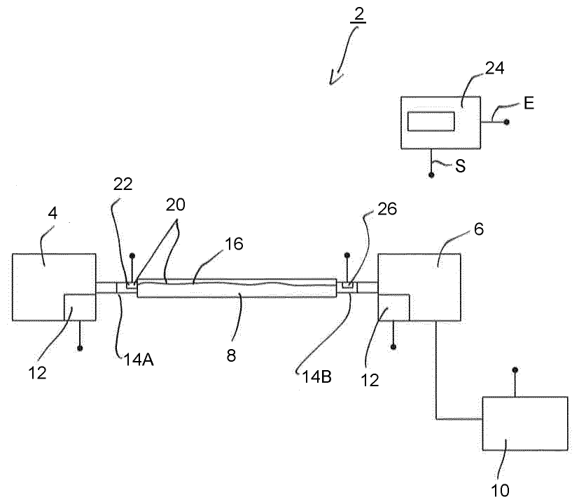

The invention relates to a method for monitoring an electrical supply system of a motor vehicle, in particular a high-voltage supply system of an electrically driven motor vehicle, having at least two components connected to each other by a cable, wherein the cable is part of the supply system.

In the automotive industry, cables are usually exposed to high, for example mechanical or thermal stresses that can influence the functionality and performance characteristics of the cable as well as its lifetime. Mechanical stresses especially include mechanical stresses caused due to vibrations, for example chafing of insulation material or influencing the electrical contact connections. Thermal stresses can occur in the area of hot (motor) components or as a result of high currents, for example.

Cables for a motor vehicle are usually designed in such way that they reliably withstand the expected stresses during their intended lifetime. Typically, cables are therefore often oversized compared to the actual requirements.

Especially in the field of high-voltage components, for example in a high-voltage drive train of an electrically driven vehicle, the stress is high not least at high electrical power levels. In this connection, both oversizing and unforeseen cable failures have to be avoided.

On this basis, the invention is based on the task of specifying a method for monitoring a supply system of a motor vehicle, in particular a high-voltage supply system, in order to ensure a reliable operation of the motor vehicle.

According to the invention, the task is solved by a method for monitoring a supply system of a motor vehicle, in particular a high-voltage supply system with the features of claim 1. Preferential embodiments are included in the dependent claims. The supply system comprises at least two electrical components connected by a cable, wherein the cable is part of the supply system. The power supply system further comprises a number of sensors designed to monitor at least one condition variable of the power supply system. The values of said condition variables determined by the at least one sensor are evaluated in a suitable manner and the functionality of the supply system is inferred based on these determined values.

In the present case, a supply system of a motor vehicle is in particular understood to be a system (permanently) installed within the vehicle, which comprises the at least two components and the cable. These are in particular high-voltage and high-performance components intended for an electric drive train for the operation of the vehicle. These high-performance components are in particular a component of the power electronics, an electric motor, in particular a traction motor for driving the vehicle, and/or a battery.

This design, especially by continuous monitoring during operation by recording the sensor data, allows a continuous monitoring of the supply system or also a monitoring of the supply system in discrete time intervals. The recorded sensor data are preferably provided with a time stamp and stored. Historical data are then compared to the currently recorded data and compared, for example, to changes or to a gradient of changes, and monitored. Based on these information, a statement about the current condition and the current functionality of the supply system is determined and especially a prognosis for the (remaining) lifetime of the supply system is also made.

Through this control and monitoring, the current condition is known practically at any time and in case of a decreasing functionality immediate measures can be taken.

The functionality of the supply system is understood to mean in particular that a statement is made regarding the entire system or also regarding partial components of said system. From the recorded sensor data, conclusions are drawn in particular regarding the functionality and quality of the electrical supply of the components. Besides this, however, preferably also a statement about the condition of the components is made based on the sensor data. For example, an increased consumption of a connected component (engine), for example caused by a defect, can be detected by measuring the temperature at the cable.

The condition variables are for example
the temperature of the cable, the connected components or even the environment,
mechanical parameters, such as information about mechanical stresses, such as bending, especially vibrations, or
electrical condition variables, which provide information about the electrical load (voltage, current, frequency).

According to a preferential embodiment, the sensor itself is integrated in the cable. In this respect, the cable insofar is an intelligent cable, which itself collects condition data via the condition variables. It is of particular importance that the condition data of the cable are used to draw conclusions about the condition of the entire system. As mentioned before, for example a temperature in the cable is used for this purpose, based on which then a statement about the condition of a component, e.g. a motor, is made or also about the condition of a connector between the component and the cable.

To form the sensor integrated in the cable, the cable preferably comprises a line element, into which a sensor signal is fed and a response signal is evaluated. The sensor signal is fed by means of a suitable feeding unit and the response signal is evaluated by an evaluation unit. The feed unit and the evaluation unit are typically arranged on the same side of the cable. The supply unit is integrated, for example in a plug of the cable or in a supply unit connected to it. The evaluation unit itself can be integrated into the supply unit or can be located at a distance from it. In the latter case, the response signal, also referred to as reflected signal, is transmitted to the evaluation unit.

The cable element is a core extending along the cable or a pair of cores or other electrical cable element.

For the evaluation of the response signal/of the reflected signal component, a propagation time measurement, for example in form of a Time Domain Reflectometry (TDR) is preferred. In this connection, a measuring pulse is fed into the sensor cores and the voltage curve of the reflected signal component or response signal is evaluated.

As an alternative to a TDR measurement, preferably a measurement method is used as described in the subsequently published WO 2018/086949 A1, the disclosure content, in particular the claims (with associated explanations) of which are hereby expressly included in the present application. Special reference is made to claims 1, 2, 6, 7 and 12 with the corresponding explanations especially on pages 5/6 and 8/9. In the course of a measuring cycle, several individual measurements are performed, wherein for each individual measurement a measuring signal (measuring pulse) is fed into the sensor cores from the feed unit, wherein a stop signal is generated in case a predetermined voltage threshold value (at the feed-in location) is exceeded as a result of the reflected signal component, wherein a propagation time between the feed-in of the measurement signal and the stop signal is determined, and wherein the voltage threshold value is modified between the individual measurements. The measuring pulse is fed in according to a measuring or sampling frequency, for example.

Therefore, exactly one stop signal is generated for each individual measurement. There is no further evaluation of the reflected signal. Due to the modified threshold value between the individual measurements, different defect locations, which thus lead to different amplitudes during the reflection, are recorded—in particular also with local resolution due to the different propagation times.

Due to the large number of individual measurements, the propagation times (stop signals) of the reflected components are generally recorded at different defined threshold values. In this respect, this method can be regarded as a voltage-discrete time measuring method. The number of individual measurements is preferably more than 10, further preferably more than 20 or even more than 50 and for example up to 100 or more individual measurements. Thus, from the large number of these individual measurements, a large number of stop signals is determined, which are arranged distributed over time. The large number of stop signals in connection with the threshold values therefore approximately reflects the actual signal course of the input measurement signal and the reflected components. Appropriately, from these stop signals the actual signal waveform for a measuring signal fed in and reflected at the end of the power is approximated by a mathematical curve fit, for example.

Due to the measuring principle according to the invention, a respective individual measurement is preferably terminated as soon as a stop signal is issued. In order to reliably check the line for the presence of several similar defect locations, each of which leading to a reflected component with comparable signal amplitudes, in a preferential embodiment a measurement dead time is specified after a first individual measurement, during which the measurement unit is practically deactivated and does not react to any stop signal. In this connection, it is especially intended that after a first individual measurement and a detected first stop signal, a second individual measurement is performed, preferably with the same threshold value as in the first individual measurement. The measurement dead time, within which no stop signal is detected, is (slightly) greater than the time between the start and the stop signal detected during the first individual measurement. This avoids that the reflected part assigned to the first stop signal is recorded in the second individual measurement. This cycle is preferably repeated several times until no further stop signal is detected. This means that the measurement dead time is respectively adapted to the propagation time of the stop (first, second, third, etc.) signal detected during the previous individual measurement, i.e. selected to be slightly greater, until to this set threshold value no further stop signal is issued.

Appropriately, a signal curve is measured by suitably adjusting the respective measurement dead time in combination with a variation of the threshold value. Thereby, especially falling edges in the signal course are also detected. Signal peaks with rising as well as falling edges can therefore be detected and evaluated.

The measuring principle of both the method described in WO 2018/086949 A1 and the TDR method is based on the fact that the propagation of the measurement signal within the line element depends on the measured condition variable. For temperature measurement, for example, a temperature-dependent dielectric is used for the conductor element, so that the propagation speed changes depending on the temperature.

Mechanical stresses or local thermal stresses lead to a local change of the dielectricity/line impedance, so that at these points a (partial) reflection of the measurement signal occurs, which is used for the evaluation. In this case, a localization of such a defect location is also possible.

In a preferential embodiment, an external sensor is arranged outside the cable, which is also intended for recording a condition variable. Appropriately, the external sensor is arranged in addition to the internal sensor of the cable. Insofar a double recording of sensor data is provided. In this connection, an external sensor is understood to mean that said sensor is not integrated in the cable. At the same time, however, the external sensor is preferably positioned at or in the immediate vicinity of the supply system. In particular, it is located inside the vehicle.

The external sensor is preferably a vibration sensor for the detection of vibrations, especially of vibrations of supply system components. Especially in the automotive sector, such unavoidable vibrations occurring during operation are a decisive mechanical stress that can lead to the impairment of electrical systems and also of their functionality.

For this purpose, the vibration sensor is located at a suitable point. Especially, the vibration sensor is located in a connection area between the cable and at least one of the two connected components. The connection is in particular a plug connection. By this measure, the vibrations are therefore directly detected and evaluated, especially in the critical connection area, in order to be able to derive statements about the current functionality of the system.

Generally, preferably an external sensor is arranged in addition to the sensor integrated in the cable. Therefore, sensor data of both the cable-internal sensor and the external sensor are considered and evaluated in order to draw conclusions about the current functionality of the supply system.

An external vibration sensor is preferably combined with a sensor integrated in the cable, such as a temperature or bending sensor. Preferably, the external sensor and the internal sensor detect different condition variables. Alternatively, the same condition variable, for example the temperature, is recorded with both sensors.

In a particularly appropriate design, based on the measured value of the external sensor a measured value received from the integrated sensor is checked and verified. Thus, it is checked whether the data delivered by the cable-internal sensor are plausible. This comparison with an external sensor reduces false diagnoses by the cable-internal sensor, for example. Especially, for example a bending sensor integrated in the cable sensor and its data are compared to the movement data of the external sensor and it is verified whether the data are plausible.

In a preferential design, for the evaluation of the received data and measured values, these are compared to a comparison system and a statement about the functionality is made based on this comparison. Within the comparison system, empirical values are deposited, for example in tabular form, so that current condition information can be derived by comparison with the comparison system.

Alternatively, the comparison system is a mathematical model, which simulates the actual system and describes it mathematically in dependence of the variable condition variables.

Appropriately, the comparison system is integrated in an evaluation unit, to which the measured data are transmitted. This evaluation unit is, for example, integrated in a control unit of the vehicle. Alternatively, however, it can also be located in a higher-level control center or in an organizational unit not belonging to the vehicle manufacturer. For example, the data received by the sensors are transmitted to the manufacturer (supplier) of the cable or the supply system, who in this way in the sense of a service monitors the functionality of the supply system, in particular continuously, i.e. during operation.

In an appropriate design, the condition variables are recorded in a large number of supply systems, especially supply systems of especially the same type installed in different vehicles, and transmitted to said higher-level, common and thus central evaluation point and evaluation unit.

The entire collected data are preferably used for a modification of the comparison system. This enables a continuous optimization and embodiment of the comparison system in order to improve the accuracy of the information.

Furthermore, in addition to the internal sensor and the external sensor, at least one other external data source, such as a vehicle control system, is preferably used and taken into account for the evaluation of the functionality. From said data source, based on the control commands, for example conclusions on the current condition of the supply system can be derived and/or the measurement data from the sensors are subjected to a plausibility check.

According to a further independent aspect, a method for monitoring a charging system of an electrically driven vehicle is intended, wherein the charging system comprises a charging column, a charging cable, a battery and a number of sensors, wherein the functionality of the charging system is inferred on the basis of the values for the condition variable determined by the sensors.

Preferably, at least one of the variables temperature, mechanical stress (for example bending, vibration) and moisture are monitored as condition variables. Preferably, the charging cable is monitored for these variables. Appropriately, several and especially all of these three variables are monitored.

The advantages and preferential designs previously mentioned with regard to the supply system in the vehicle are to be transferred in the same way to the charging system. The explanations regarding the cable are therefore to be transferred to the charging cable.

Generally, the method described here is not necessarily limited to the application in the automotive sector. Alternatively, it is also applied to electrical supply systems, for example in (industrial) plants, in which electrical components, especially consumers, are supplied with energy via a cable.

An exemplary embodiment of the invention is explained below in more detail based on the FIGURE. Said FIGURE shows a schematic, highly simplified view of an electrical supply system of a motor vehicle, especially of a high-voltage supply system.

The FIGURE shows a supply system 2, which comprises a first component 4, a second component 6 and a cable 8 connecting these two components 4,6. The first component is in particular a vehicle battery 4, the second component 6 is in particular a power electronics, such as an inverter and especially an electric motor 6, which is designed as a traction or drive motor to drive the electrically operable vehicle. The drive motor 6 is connected to a control unit 10. The two components 4,6 can also have integrated monitoring units 12, which, for example, record condition variables of these two components 4,6, such as temperature, current consumption or current output, etc. The cable 8 is connected to the battery 2 on the one hand and on the other hand to the electric motor 6 via the connections 14A,14B. Said connections can for example be plug connectors. Alternatively, the individual supply lines of cable 8 are permanently connected, for example by clamps, screw terminals, etc.

The cable 8 is generally a power supply cable, typically comprising several electrical supply cores, designed to transmit the required power between the battery 4 and the electric motor 6. During operation, this high-voltage system will transmit powers of several 10 kW, typically more than 50 kW and further typically more than 100 kW. Electrical drive powers are often in the range of 100 to 200 kW. For larger vehicles or higher power ratings, electrical powers of up to 500 kW or even up to almost 1,000 kW are also transmitted. The voltage for such systems is typically in the range of several 100 volts.

In the exemplary embodiment, furthermore a line element 16, in the following also referred to as the sensor cable, is integrated into cable 8. This sensor line is used for to record an internal condition variable of the cable 8. In this respect, the line element 16 is part of an integrated sensor 20 of the cable 8. Alternatively, a discretely arranged sensor could be arranged in the cable 8 or at several points of the cable 8.

The sensor based on the line element 16, respectively the method for determining a value of a condition variable, such as the temperature of the cable, is based on the fact that a measuring signal is fed into the line element 16 and a response signal is determined. The response signal is typically a reflected signal. This design is based on the consideration that due to defects within the cable, reflections occur within the measuring core (line element 16) and are re-reflected. The measuring signal is fed in by means of a feed unit 22. The reflected signal runs back to the feed unit 22 and is, for example, directly selected there or transmitted to an evaluation unit 24. The power supply unit 24 is integrated in a connector 14 A, for example.

In addition, a further, external sensor 26 is provided, which is designed as a vibration sensor. Said external sensor is located at critical, vibration-stressed points, preferably in the connection area 14B towards the second component 6. There, in particular high-frequency vibrations occur due to operation, since the electric motor 6 is connected to a drive axle and thus vibrations are transmitted through the contact with the road. The connection point to battery 4, on the other hand, is less stressed.

Furthermore, at a reference point another vibration sensor can be arranged, which serves as a reference base and as a basis for comparison.

The evaluation unit 24 is designed to receive sensor data preferably from both the integrated sensor 20 as well from the external sensor 26. The data of said sensors 20,26 are recorded as sensor data S. In addition, preferably further measurement data or information about the condition variables are recorded, which, for example, originate from further external sensors and sensors arranged outside the supply system or from the monitoring units 12 or from the control unit 10. The corresponding information are transmitted to the evaluation unit 24 as external data E. Based on the transmitted current data, the evaluation unit 24 determines the current functional condition. Depending on the current functional condition, in a preferential design the operation is then controlled or regulated; especially if a functional impairment was detected, this is used for a current limitation.

Furthermore, it is intended to make a prediction of the expected remaining lifetime on the basis of the transmitted sensor data. For this purpose, for example a comparison system is deposited in the evaluation unit 24, especially a mathematical model, which maps the supply system 2 and on the basis of which the influence of the values of the individual condition variables on the actual supply system 2 can be simulated and evaluated for predictions.

According to an alternative use, the supply system 2 is designed as a charging system, wherein in this case one of the two components 4,6 represents a charging column and the other the vehicle battery 4. In this case, the cable 8 is designed as a charging cable.

The explanations regarding the supply system are analogously also applied to the charging system.

Due to the need to reduce the charging time, high performance charging systems are being worked on. In this connection, charging capacities of 500 A and more at 1000V are being developed concretely, which is not yet the limit, especially with regard to the fast charging of trucks. For charging capacities beyond 500 kW, the topic of safety takes on a new significance. Especially in cooled charging systems, in terms of temperature the charging line is the warmest element in the charging system.

By the integration of continuously measuring sensors 20,26, as previously described, for example the average line temperature of the charging cable and/or a localization of a hotspot can be recorded. Two differently arranged sensor elements 20,26 are preferably used to differentiate between heating from the inside (by high charging current) or heating from the outside (for example solar radiation). The internal temperature of the charging cable is preferably detected by the integrated sensor 20 and the temperature acting from the outside is preferably detected by the external sensor 26.

According to a preferential design, the sensor, in particular the integrated sensor 20, is designed to detect a liquid intrusion into the interior of the charging cable 8, which indicates a crack in the outer sheath (intrusion of rainwater, for example) or a crack in the internal cooling tubes (leakage of cooling liquid) and is accordingly also detected by the evaluation.

Preferably, in this connection a signal characterization is used to differentiate between the type of liquid in particular. Such sensor, again, is designed as for example integrated sensor 20 in the cable 8 with the line element 16 (sensor line), into which a measuring pulse is fed. Its spread is characteristically changed when the liquid is present.

Preferably, a further or a combined sensor is integrated, which is able to detect mechanical influences. Depending on the design of the sensor 20 (line element 16) and/or by a suitable feeding and evaluation of the fed measuring pulse, in particular by a variably adjustable sampling frequency, with which the measuring pulse is fed, the sensitivity of the sensor may be designed according to the desired statement.

As an example, a change could be detected here from a permanent deformation (vehicle standing on the charging cable 8) up to the dynamic detection of temporary bends (for example when plugging in).

In addition to the integrated sensor 20, a further external sensor 26 is preferably also provided for the charging system. Said further external sensor is, for example, a temperature sensor, which is preferably installed in or on a charging plug via which the charging cable 8 is connected to an energy source or energy sink.

As previously described for the supply system, a connection to the external sensor 26 and/or other data sources is preferably implemented. This serves to check the plausibility of the signals generated by the internal sensor 20 on the one hand. On the other hand, the further data sources or external sensors 26 detect and determine findings about further dependencies and their effects on the charging cable (pattern recognition). In turn, this is used to improve and to specify the statements for functionality, e. g. the probability of failure, for example by adapting the previously described comparison system. As data sources in particular a weather database for a current ambient temperature is used. Alternatively or in addition, a charging control system is used as an additional data source, for example in the charging station or in the vehicle, through which current and voltage curves during the charging process are calculated.

By comparing the recorded sensor data with the comparison system described above, statements about the functionality are made. For example, either ad hoc messages are generated in case of critical conditions. In such a case, the charging system is preferably shut down, respectively switched off. I.e. in the charging system, for example, the charging current is controlled depending on the determined current condition of the cable.

Besides this, preferably also creeping effects (continuous signal drifts) are compared to the comparison system and/or to historical measuring data of the sensors. By means of a usage history, i.e. comparison with historical measurement data, on the basis of which statements about the previous usage can be derived, preferably prognoses about the (remaining) lifetime are derived. This helps to ensure a smooth charging operation.

The evaluation of a usage history especially for a statement about a remaining lifetime is equally applied to the supply system in the previously described vehicle.

Altogether, the monitoring of the supply system described here, especially of the monitored charging system, provides a high operational safety as well as a high operational utilization of the supply system. By the in particular continuous monitoring, the entire supply system can therefore be designed in an optimized way and the safety margins for the structural design, such as conductor cross sections, can be reduced.

The high level of safety, especially regarding the charging cable, ensures that the user does comes into contact with an overheated or mechanically damaged cable at any time. Furthermore, the charging processes can thereby be optimized in order to achieve the highest possible degree of utilization for the operator (active control of charging and cooling processes).

In a preferential embodiment, an information exchange of the charging system with other elements of a charging infrastructure is provided. Especially, an exchange of information between supply network (energy supplier)—charging station—charging cable—vehicle (inlet-box, HV wiring up to the battery) is provided. This results in mutual dependencies, which lead to an optimal utilization of the entire charging line. The conditions of the lines are seen as essential, controlling elements, whether in the supply network, the charging line or the on-board network of the vehicle.

1-17. (canceled)

18. A method for monitoring a supply system of a motor vehicle, the supply system having at least two electrical components connected to each other via a cable, the cable being part of the supply system, which comprises the steps of:
monitoring, via a plurality of sensors, at least one condition variable of the supply system; and
inferring a functionality of the supply system from values for the at least one condition variable determined by the sensors.

19. The method according to claim 18, wherein one of the sensors is integrated in the cable and is an integrated sensor.

20. The method according to claim 18, wherein one of the sensors is formed by a line element of the cable into which a sensor signal is fed and a response signal is evaluated.

21. The method according to claim 20, which further comprises performing several individual measurements in a course of a measuring cycle, wherein:
per individual measurement a measuring signal is fed into the line element;
a stop signal is generated, in a case where a predetermined threshold value is exceeded due to a reflected measurement signal component and the individual measurement is terminated;
a propagation time between an input of the measuring signal and the stop signal is generated; and
the predetermined threshold value is modified between the individual measurements.

22. The method according to claim 21, wherein after detection of a first stop signal in a first individual measurement, a second individual measurement is performed, wherein in the second individual measurement a measurement dead time is specified, which is greater than a propagation time for the first stop signal detected in the first individual measurement, so that a reflected component associated with the first stop signal is not detected in the second individual measurement.

23. The method according to claim 18, wherein one of said sensor is an external sensor disposed outside the cable for a detection of the at least one condition variable.

24. The method according to claim 23, wherein the external sensor is a vibration sensor.

25. The method according to claim 24, wherein the vibration sensor is disposed at a connection between the cable and one of the two electrical components.

26. The method according to claim 19, wherein in addition to the one sensor integrated in the cable, another of the sensors is an external sensor disposed outside the cable and a measured value of the external sensor is evaluated in addition to the sensor integrated in the cable in order to conclude a current functionality of the supply system.

27. The method according to claim 26, which further comprises classifying a measured value obtained from the integrated sensor is classified as OK or not OK based on the measured value of the external sensor.

28. The method according to claim 18, wherein measured values determined for condition variables are compared to a comparison system and a statement about the functionality is made.

29. The method according to claim 28, wherein the at least one condition variable is recorded for a large number of supply systems, transmitted to a higher-level, common central evaluation point and used for a modification of the comparison system.

30. The method according to claim 18, wherein at least one further data source is used and taken into account for an evaluation of the functionality.

31. The method according to claim 18, wherein the supply system is a high-voltage supply system of an electrically driven motor vehicle.

32. The method according to claim 22, wherein the second individual measurement is performed with a same threshold value as in the first individual measurement.

33. The method according to claim 30, wherein the at least one further data source is a vehicle control system.

34. A method for monitoring a charging system of an electrically driven motor vehicle having at least two electrical components connected to each other via a charging cable, namely a charging column and a battery, wherein the charging system having a plurality of sensors, which comprises the steps of:
monitoring at least one condition variable of the charging system via the plurality of sensors; and
inferring a functionality of the charging system from values determined by the sensors for the at least one condition variable.

35. The method according to claim 34, which further comprises monitoring the charging cable for temperature, mechanical stresses and moisture penetration by means of one of the sensors being a sensor integrated in the charging cable.

36. The method according to claim 34, which further comprises obtaining values of a current charging current or a current charging voltage via a charging control and the values are used to check a plausibility of the values determined by the sensors.

37. The method according to claim 34, wherein an internal condition variable is recorded by one of the sensors being a sensor integrated in the charging cable and in which a condition variable outside the charging cable is recorded by means of another one of the sensors being an external sensor.
